(19) United States
(12) Patent Application Publication
(10) Pub. No.: US 2024/0332398 A1
(43) Pub. Date: Oct. 3, 2024

(54) HIGH DENSITY METAL-INSULATOR-METAL CAPACITOR

(71) Applicant: International Business Machines Corporation, Armonk, NY (US)

(72) Inventors: Ruilong Xie, Niskayuna, NY (US); Roy R. Yu, Poughkeepsie, NY (US); SON NGUYEN, Schenectady, NY (US)

(21) Appl. No.: 18/191,295

(22) Filed: Mar. 28, 2023

(51) Int. Cl. H01L 29/66; H01L 21/8234; H01L 23/522; H01L 23/528; H01L 27/088; H01L 29/06; H01L 29/423; H01L 29/775; H01L 29/78; H01L 29/786

(52) U.S. Cl. CPC H01L 29/66545; H01L 21/823431; H01L 21/823475; H01L 23/5223; H01L 23/5286; H01L 27/0886; H01L 29/0673; H01L 29/42392; H01L 29/66439; H01L 29/66795; H01L 29/775; H01L 29/785; H01L 29/78696

(57) ABSTRACT

A semiconductor structure with a nanosheet device region with GAA nanosheet FETs on a bottom dielectric isolation layer. The GAA nanosheet FETs connect by a frontside contact to the frontside back-end-of-line (BEOL) interconnect wiring and by a backside contact to the backside BEOL interconnect wiring. The semiconductor structure includes a finFET device region with one or more finFET devices on bottom interlayer dielectric material. The finFET devices with a thick gate oxide connect by a frontside contact to the frontside BEOL interconnect wiring. The semiconductor structure also includes a three-dimensional MIM capacitor region with one or more three-dimensional MIM capacitors. The three-dimensional MIM capacitors with a high capacitance have a fin-like backside metal plate covered by a high-k dielectric material or super capacitor materials that is under a frontside metal plate. The three-dimensional MIM capacitors connect to the frontside BEOL interconnect wiring and the backside BEOL interconnect wiring.

### BACKGROUND

The present invention relates generally to the field of semiconductor device manufacture and more particularly to the formation of three-dimensional semiconductor structures for high density metal-insulator-metal capacitors.

The amount of data we process is rapidly increasing at a rate higher than that of Moore's law. Increasing system performance requirements, driven at least in part by the increasing use of artificial intelligence, continue to drive tighter pitches in semiconductor devices and smaller semiconductor chips. To meet this growing demand, in addition to conventional scaling, the semiconductor memory industry is exploring other options such as multi-level cell, three-dimensional stacking, and multi-layer structures to improve logic and memory density.

A finFET device is a type of field-effect transistor (FET) that has a thin vertical fin instead of being completely planar. FinFET devices are an emerging three-dimensional semiconductor device structure. The gate is fully wrapped around the channel on three sides of the channel. In finFET devices, the channel resides in the thin vertical fins and a thick oxide can be provided with finFET device gates. The fins are formed between the source and the drain. FinFET devices exhibit superior short channel behavior, have lower switching times, and have a higher current density than conventional planar MOSFET technology. For FinFETs of the 5 nanometer (nm) technology node and beyond, the channel control capability is not sufficient due to short channel effects.

For logic scaling at the two-nanometer node, planar and non-planar semiconductor device structures, such as metal-oxide-semiconductor FETs, must be scaled to smaller dimensions to provide increased device width per footprint area. In this regard, Gate All Around (GAA) nanosheet (or nanowire) FET devices are a viable option for continued scaling. GAA nanosheet FET devices have been recognized as excellent candidates to achieve improved power performance and area scaling compared to FinFET technology. GAA nanosheet FET devices can provide high drive currents due to wide effective channel width (Weff) while maintaining short-channel control.

In general, GAA nanosheet FET devices are composed of a device channel having a nanosheet stack with one or more nanosheet layers, with each nanosheet layer having a vertical thickness substantially less than the width of the nanosheet layer. A common gate structure may be formed above and below each nanosheet layer in the stacked configuration, thereby increasing the GAA nanosheet FET device width (or channel width). Accordingly, such GAA nanosheet FET devices may increase the drive current for a given footprint area aiding in device footprint reduction and the increasing device performance demands of the industry.

Capacitors also have inherent limitations for continued cell scaling. For example, to ensure enough noise margin, the capacitance for a memory cell must be maintained at a relatively constant value regardless of technology scaling. Since the memory cell capacitance is directly related to the surface area of the capacitor, as the memory cell and capacitor size shrinks, a decrease in capacitance typically occurs.

In general, capacitors are important for energy storage, signal filtering, and high-frequency tuning applications. Metal-insulator-metal (MIM) capacitors are a basic building block of electronic systems. On-chip MIM capacitors are a critical element in analog, mixed-signal application-specific integrated circuits (ASIC), and radio frequency complementary-metal-oxide semiconductor (CMOS) designs.

Typically, MIM capacitors are widely used in high-performance microprocessor design for on-chip decoupling functions to help mitigate the power supply noise problem. A typical MIM capacitor is formed by two parallel metal layers that have a high k-dielectric material between the two parallel metal layers. Factors impacting the performance of the MIM capacitor include, for instance, the dielectric constant and thickness of the insulator, the type of metal for the electrodes to optimize the pairing with a given insulator, and the total MIM capacitor area.

As the semiconductor industry continues to drive tighter pitches and feature sizes in semiconductor devices increasing performance, another semiconductor device trend aiding in miniaturization is the addition of backside interconnect layers that can be used as a backside power delivery network. Creating backside interconnect layers below the front-end-of-line semiconductor devices offers more routing options for semiconductor devices and especially densely packed three-dimensional semiconductor devices such as GAA nanosheet FET devices. Moving some of the wiring in middle-of-line (MOL) and back-end-of-line (BEOL) wiring and power distribution features to the backside interconnect wiring layers, relaxes the MOL and the BEOL wiring congestion. Backside interconnect wiring is another important industry trend to aide in attaining device miniaturization for the two-nanometer nodes and beyond while also achieving device performance requirements.

### SUMMARY

Embodiments of the present invention provide a semiconductor structure composed of a nanosheet device region, a finFET device region, and a three-dimensional MIM capacitor region in a semiconductor chip. The semiconductor chip has backside back-end-of-line (BEOL) interconnect wiring and is bonded to a carrier wafer. The combination of the gate-all-around (GAA) nanosheet field-effect transistors (FETs) formed in the nanosheet region with the finFET devices in the finFET region, and the fin-like three-dimensional metal-insulator-metal (MIM) capacitor provides an ability for continued scaling in the two-nanometer node.

The GAA nanosheet FETs provide both improved power performance and the arca scaling needed in the two-nanometer node compared to finFET technology. FinFET devices in the finFET device region provide a long channel and use a thick gate oxide needed for input/output (I/O) devices. Forming the I/O devices with long channels and a thick gate oxide is not feasible in GAA nanosheet FETs due to the tight spacing between nanosheet channels in the GAA nanosheet FETs. To provide I/O devices with a thick gate oxide and long channels, finFET devices are formed in conjunction with GAA nanosheet FETs in embodiments of the present invention. The fin-like three-dimension MIM capacitors can be formed in conjunction with the finFET devices using fin formation processes to provide additional capacitance to the GAA nanosheet FETs through the backside BEOL interconnect wiring and to the finFET devices by the frontside BEOL wiring. The fin-like three-dimensional MIM capacitors use a plurality of vertical metal fins that replace the silicon fins formed with the finFET devices. The vertical metal fins on a metal plate on the backside interlayer dielectric are covered by a high-k dielectric material under a frontside metal plate.

Using the vertical metal fins to form the fin-like three-dimensional MIM capacitor provides more of the dielectric material area where the high-k dielectric material is between the frontside metal plate and the backside metal plate. The fin-like three-dimensional MIM capacitors provide a much smaller footprint area than a conventional two-dimensional MIM capacitor generating the same capacitance and, in this way, the fin-like three-dimensional MIM capacitors support device miniaturization. With an ability to generate more capacitance in the same device area, the fin-like three-dimensional MIM capacitors aide in the ability of the semiconductor chip to improve electrical performance. Combining GAA nanosheet FETs with finFET devices, and fin-like, three-dimensional MIM capacitors, as disclosed in embodiments of the present invention, provides solutions to both device scaling requirements and device electrical performance for the two-nanometer node.

The GAA nanosheet FETs and the finFET devices are on a bottom dielectric isolation layer. The GAA nanosheet FETs connect to the finFET devices through the frontside BEOL interconnect wiring by a first frontside contact. The GAA nanosheet FETs connect to the fin-like three-dimensional MIM capacitors through the backside BEOL interconnect wiring with the first backside contact. These connections provide improved electrical performance by providing access to I/O devices, additional capacitance, and reduced BEOL wiring congestion. The ability to provide backside BEOL interconnect wiring which can be a backside power delivery network alleviates frontside BEOL interconnect wiring by moving some of the power delivery functions and wiring from the frontside BEOL interconnect wiring to the backside BEOL interconnect wiring. Providing the ability to remove a portion of the frontside BEOL wiring by moving the wiring to the backside BEOL interconnect wiring can provide additional area for device formation.

### BRIEF DESCRIPTION OF THE DRAWINGS

The above and other aspects, features, and advantages of various embodiments of the present invention will be more apparent from the following description taken in conjunction with the accompanying drawings.

FIG. 1A depicts a top view of a nanosheet device region, in accordance with an embodiment of the present invention.

FIG. 1B depicts a top view of a finFET device region, in accordance with an embodiment of the present invention.

FIG. 1C depicts a top view of a metal-insulator-metal (MIM) capacitor region, in accordance with an embodiment of the present invention.

FIG. 2 depicts a cross-sectional view of a portion of the semiconductor structure on a substrate, in accordance with an embodiment of the present invention.

FIG. 3 depicts cross-sectional views X-X, Y1-Y1, and Y2-Y2 of the semiconductor structure after hard mask patterning, removing the nanosheet layers from the finFET device region and the MIM capacitor region, in accordance with an embodiment of the present invention.

FIG. 4 depicts cross-sectional views X-X, Y1-Y1, and Y2-Y2 of the semiconductor structure after growing a layer of the bottom sacrificial material on the silicon epitaxy layer in the finFET device region and the MIM capacitor region, in accordance with an embodiment of the present invention.

FIG. 5 depicts cross-sectional views X-X, Y1-Y1, and Y2-Y2 of the semiconductor structure after patterning an optical planarization layer (OPL) and removing the bottom sacrificial material from the MIM capacitor region, in accordance with an embodiment of the present invention.

FIG. 6 depicts cross-sectional views X-X, Y1-Y1, and Y2-Y2 of the semiconductor structure after epitaxially growing a semiconductor material layer on a top surface of the finFET device region and the MIM capacitor region, in accordance with an embodiment of the present invention.

FIG. 7 depicts cross-sectional views X-X, Y1-Y1, and Y2-Y2 of the semiconductor structure after fin and shallow isolation trench (STI) formation in the finFET device region and the MIM capacitor region, in accordance with an embodiment of the present invention.

FIG. 8 depicts cross-sectional views X-X, Y1-Y1, and Y2-Y2 of the semiconductor structure after dummy gate patterning, in accordance with an embodiment of the present invention.

FIG. 9 depicts cross-sectional views X-X, Y1-Y1, and Y2-Y2 of the semiconductor structure after the bottom sacrificial material removal in the nanosheet region and the finFET device region, in accordance with an embodiment of the present invention.

FIG. 10 depicts cross-sectional views X-X, Y1-Y1, and Y2-Y2 of the semiconductor structure after depositing the gate spacer and bottom dielectric isolation (BDI), in accordance with an embodiment of the present invention.

FIG. 11 depicts cross-sectional views X-X, Y1-Y1, and Y2-Y2 of the semiconductor structure after recessing the channel material, forming inner spacers, source/drains, and ILD deposition in the nanosheet device region, in accordance with an embodiment of the present invention.

FIG. 12 depicts cross-sectional views X-X, Y1-Y1, and Y2-Y2 of the semiconductor structure after dummy gate and sacrificial material removal in the nanosheet device region, and dielectric deposition, in accordance with an embodiment of the present invention.

FIG. 13 depicts cross-sectional views X-X, Y1-Y1, and Y2-Y2 of the semiconductor structure after depositing the metal gate and performing a chemical-mechanical polish (CMP), in accordance with an embodiment of the present invention.

FIG. 14 depicts cross-sectional views X-X, Y1-Y1, and Y2-Y2 of the semiconductor structure after middle-of-line (MOL) and back-end-of-line (BEOL) interconnect formation, in accordance with an embodiment of the present invention.

FIG. 15 depicts cross-sectional views X-X, Y1-Y1, and Y2-Y2 of the semiconductor structure after bonding a carrier wafer to the top surface of the BEOL interconnect, in accordance with an embodiment of the present invention.

FIG. 16 depicts cross-sectional views X-X, Y1-Y1, and Y2-Y2 of the semiconductor structure after wafer flip and substrate removal, in accordance with an embodiment of the present invention.

FIG. 17 depicts cross-sectional views X-X, Y1-Y1, and Y2-Y2 of the semiconductor structure after etch stop layer removal, in accordance with an embodiment of the present invention.

FIG. 18 depicts cross-sectional views X-X, Y1-Y1, and Y2-Y2 of the semiconductor structure after selectively removing the semiconductor material, in accordance with an embodiment of the present invention.

FIG. 19 depicts cross-sectional views X-X, Y1-Y1, and Y2-Y2 of the semiconductor structure after backside metal plate deposition in the MIM capacitor region, in accordance with an embodiment of the present invention.

FIG. 20 depicts cross-sectional views X-X, Y1-Y1, and Y2-Y2 of the semiconductor structure after backside interlayer dielectric (ILD), backside contacts in the nanosheet device region, and the MIM capacitor region, and forming backside BEOL interconnects, in accordance with an embodiment of the present invention.

### DETAILED DESCRIPTION

Embodiments of the present invention recognize at the two-nanometer (nm) node, and beyond, semiconductor device structures must be scaled to smaller dimensions to provide increased device width per footprint area. Gate All Around (GAA) nanosheet (or nanowire) FET devices are composed of a device channel having a nanosheet stack with one or more thin nanosheet layers, with each nanosheet layer having a vertical thickness, typically in the range of 3 to 10 nm, that is substantially less than the width of the nanosheet layer. A common gate structure may be formed above and below each nanosheet layer in the stacked configuration which increases the channel width of the GAA nanosheet FET devices. GAA nanosheet FET devices are suitable for high-performance logic as device technologies move into the 2 nm node. With the increased channel width, the GAA nanosheet FET devices may increase the drive current for a given footprint area aiding in device footprint reduction and the increasing device performance demands of the industry.

However, embodiments of the present invention recognize that input/output (I/O) devices typically have a long channel and use a thick gate oxide. Forming the I/O devices is not feasible in GAA nanosheet FET devices. Creating a thick gate oxide will pinch off the space between the nanosheet layer. The space between the nanosheet layers is needed to deposit the gate electrode material for the gate stack. To provide I/O devices with the thick gate oxide and long channels, finFET devices, formed in conjunction with GAA nanosheet FET devices, can provide the thick gate oxide and long channels required by I/O devices. For advanced device technologies moving into the 2 nm, finFET devices providing thick gate oxides for I/O devices will be needed on the same wafer and/or semiconductor chip as the high-performance logic provided by the GAA nanosheet FET devices.

Additionally, embodiments of the present invention recognize that as device and device feature sizes continue to reduce following Moore's Law along with increasing performance requirements, middle-of-line (MOL) and back-end-of-line (BEOL) wiring congestion will occur along with a need to reduce power supply insulation resistance (IR) drop due reduced feature size and reduce space between features such as power planes. In order to reduce MOL and BEOL wiring congestion and reduce power supply IR drop, advanced semiconductor chips in the 2 nm node can provide backside BEOL interconnect wiring such as a backside power delivery network. Backside BEOL interconnect wiring can replace the semiconductor substrate after wafer grinding. Formed, for example, on a layer of backside interlayer dielectric that is below FEOL devices, the backside BEOL interconnect wiring can be connected by backside contacts to logic devices including GAA nanosheet FET devices and passive devices such as capacitors to reduce MOL and BEOL wiring congestion and improve power supply IR drop.

Embodiments of the present invention provide a semiconductor structure on a single semiconductor wafer or semiconductor chip substrate providing the required device performance as semiconductor device technology evolves into the 2 nm technology node. Embodiments of the present invention provide a semiconductor structure with multiple types of advanced semiconductor devices to support the device scaling required for the 2 nm technology node and a method to form the advanced semiconductor devices on a semiconductor substrate. To support high-performance logic in the 2 nm node, embodiments of the present invention disclose at least one GAA nanosheet FET device formed with at least one finFET device to provide I/O device functionality and backside BEOL wiring to reduce wiring congestion and IR power supply drop as device feature size reduction progresses along with semiconductor performance increases. Additionally, to further improve both wiring congestion and device performance, a high density, three-dimensional metal-insulator-metal (MIM) capacitor is formed on the backside interlayer dielectric material replacing the original semiconductor wafer. The high density, three-dimension MIM capacitor formed, along with the finFET device from epitaxially grown fins, connects to both the frontside BEOL interconnect wiring and the backside interconnect wiring to provide capacitance to both the finFET device and the GAA nanosheet FET device.

Embodiments of the present invention disclose the high density, three-dimensional MIM capacitor formed with the same or similar process as the finFET device structure disclosed herein. The fin-like, high density, three-dimensional MIM capacitor or hybrid MIM capacitor uses a high-k dielectric material or a super high-k dielectric material as the insulator that is between the two metal layers (i.e., a top metal that can be deposited as a gate metal and a lower fin-like metal plate). The fin-like, high-density, three-dimensional MIM capacitor can be formed by removing the epitaxially formed silicon fins which are covered by a high-k or a super high-k dielectric material. Using a metal to replace or fill the gaps previously containing the silicon fins and forming a plate below the metal fins and between the metal fins which are covered by the high-k dielectric material directly under the metal gate material forms a MIM capacitor. The fin-like, high density, three-dimensional MIM capacitor disclosed in embodiments of the present invention includes a high-k or super high-k dielectric insulator between the upper gate metal and the bottom metal plate which has the fin-like vertical extensions. The bottom metal plate with the fin-like vertical extensions directly under the high-k dielectric material which is between the top gate metal and the bottom metal plate provides a large vertical contact area of the two metal plates (i.e., the top gate metal and the bottom metal plate). The fin-like, high density, three-dimensional MIM capacitor with the large contact area of the high-k dielectric material with the top gate metal and the bottom metal plate provides a large capacitance without a large MIM capacitor footprint. The fin-like, high density MIM capacitor both provides more capacitance and a reduced MIM capacitor footprint compared to a conventional two-dimensional MIM capacitor. With top and bottom connections to both the frontside and backside BEOL interconnect wiring and the GAA nanosheet FET devices and finFET devices provides a close, fast, reliable, and stable power source to the GAA nanosheet FET devices and finFET devices in the semiconductor chip. Providing a fin-like three-dimensional MIM capacitor with a large contact area of the dielectric material between the two metal layers of the MIM capacitor, especially with high epsilon super capacitor, increases a capacitance of the three-dimensional MIM capacitor compared to a conventional MIM capacitor with the same footprint.

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Some of the process steps, depicted, can be combined as an integrated process step. In addition, descriptions of well-known functions and constructions may be omitted for clarity and conciseness.

The terms and words used in the following description and claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces unless the context clearly dictates otherwise.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” or “contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

Detailed embodiments of the claimed structures and methods are disclosed herein. The method steps described below do not form a complete process flow for manufacturing integrated circuits on semiconductor chips. The present embodiments can be practiced in conjunction with the integrated circuit fabrication techniques for semiconductor chips and devices currently used in the art, and only so much of the commonly practiced process steps are included as are necessary for an understanding of the described embodiments. The figures represent cross-section portions of a semiconductor chip or a substrate, such as a semiconductor wafer during fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment,” etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

The terms “epitaxially growing and/or depositing” and “epitaxially grown and/or deposited” mean the growth of a semiconductor material on a deposition surface of a semiconductor material, in which the semiconductor material being grown has the same crystalline characteristics as the semiconductor material of the deposition surface. In an epitaxial deposition process, the chemical reactants provided by the source gases are controlled and the system parameters are set so that the depositing atoms arrive at the deposition surface of the semiconductor substrate with sufficient energy to move around on the surface and orient themselves to the crystal arrangement of the atoms of the deposition surface. Therefore, an epitaxial semiconductor material has the same crystalline characteristics as the deposition surface on which it is formed.

Deposition processes for the metal materials and sacrificial material include, e.g., chemical vapor deposition (CVD), physical vapor deposition (PVD), atomic layer deposition (ALD), or gas cluster ion beam (GCIB) deposition. CVD is a deposition process in which a deposited species is formed because of a chemical reaction between gaseous reactants at greater than room temperature (e.g., from about 25 C. about 900 C.). The solid product of the reaction is deposited on the surface on which a film, coating, or layer of the solid product is to be formed.

Various materials are referred to herein as being removed or “etched” where etching generally refers to one or more processes implementing the removal of one or more materials while leaving other protected areas of the materials that are masked during the lithography processes unaffected. Some examples of etching processes include but are not limited to the following processes, such as a dry etching process using a reactive ion etch (RIE) or ion beam etch (IBE), a wet chemical etch process, or a combination of these etching processes. A dry etch may be performed using a plasma. Ion milling, sputter etching, or reactive ion etching (RIE) bombards the wafer with energetic ions of noble gases that approach the wafer approximately from one direction, and therefore, these processes are an anisotropic or a directional etching process. Selectively etching as used herein includes but is not limited to patterning using one of lithography, photolithography, an extreme ultraviolet (EUV) lithography process, or any other known semiconductor patterning process followed by one or more the etching processes.

Reference will now be made in detail to the embodiments of the present invention, examples of which are illustrated in the accompanying drawings, wherein like reference numerals refer to like elements throughout.

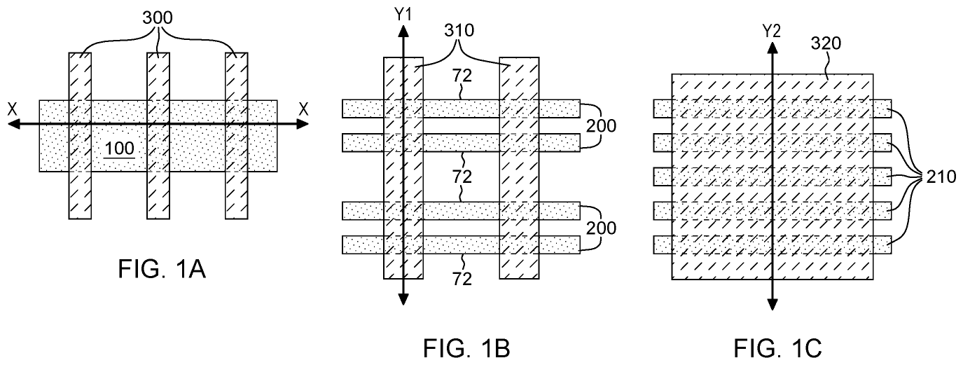

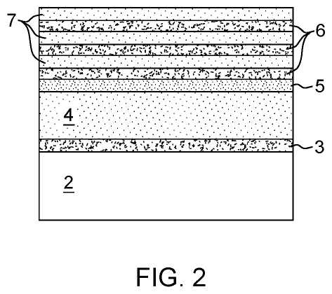

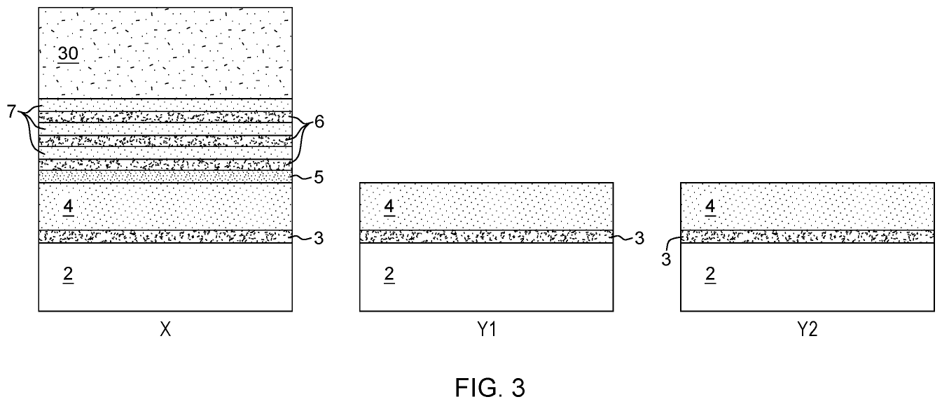

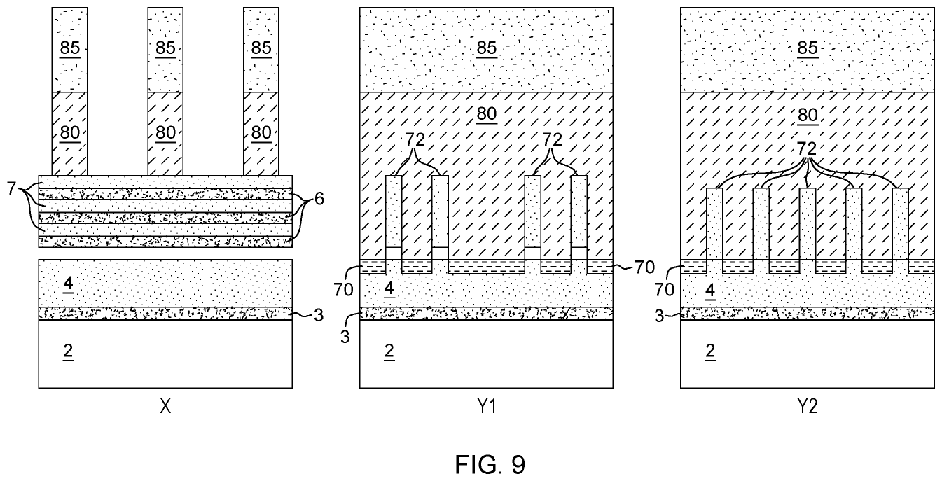

FIG. 1A depicts a top view of nanosheet device designs in the nanosheet device region, in accordance with an embodiment of the present invention. FIG. 1A depicts an example of a nanosheet device design that includes gate structures 300 extending perpendicular to a nanosheet device region 100. Also depicted in FIG. 1A is a location of cross-section X-X in FIGS. 3-20. Nanosheet device region 100 is formed from the nanosheet stack depicted in FIG. 2 using the process steps discussed regarding cross-section X-X in FIGS. 3-20. Gate structure 300, as known to one skilled in the art, may include at least a first gate dielectric material (not depicted) and a metal gate material deposited over and around the gate dielectric material as discussed later with respect to FIGS. 9-20.

FIG. 1B depicts a top view of the finFET device designs in the finFET device region, in accordance with an embodiment of the present invention. FIG. 1B depicts an example of a finFET device design that includes gate structures 310 extending perpendicular to fins 200 of the finFET devices in the finFET device region of FIG. 1B. Fins 200 and gate structure 310 with at least a second gate dielectric material (not depicted) and gate metal material can be formed in the finFET device region of FIG. 1B. Also depicted in FIG. 1B is a location of cross-section Y1-Y1 in FIGS. 3-20.

FIG. 1C depicts a top view of the hybrid MIM capacitor device design in a MIM capacitor region, in accordance with an embodiment of the present invention. FIG. 1C depicts an example of a hybrid MIM capacitor design that includes frontside metal plate 320 over the fins of backside metal plate 210 that extend above the shallow trench isolation layer. In various embodiments, backside metal plate 210 is under a third dielectric material (not depicted). Not depicted in FIG. 1C are the portions of backside metal plate 210 under the shallow isolation layer. (MIM) capacitor region, in accordance with an embodiment of the present invention. Also depicted in FIG. 1B is a location of cross-section Y2-Y2 in FIGS. 3-20. In various embodiments, frontside metal plate 320, gate structures 310, and gate structures 300 are composed of different electrically conductive materials or metal materials. In an embodiment, one or more of frontside metal plate 320, gate structures 310, and gate structures 300 are composed of the same electrically conductive material, metal, or metal alloy.

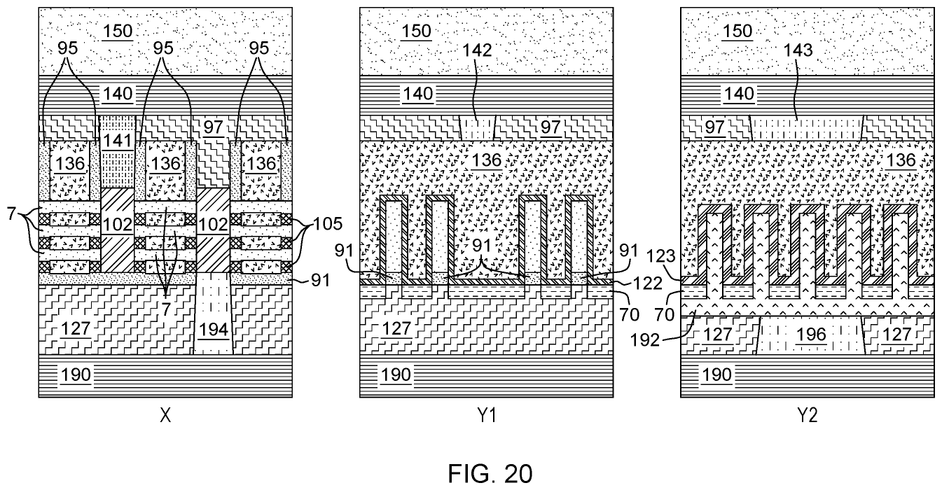

FIG. 2 depicts a cross-sectional view of a portion of semiconductor structure for a nanosheet stack on substrate 2, in accordance with an embodiment of the present invention. As depicted, FIG. 2 includes the nanosheet stack composed of alternating layers of sacrificial material 6 and channel material 7 above bottom sacrificial layer 5. Bottom sacrificial layer 5 is over a layer of semiconductor 4 and etch stop 3 is directly under semiconductor 4 and on substrate 2 in FIG. 2. The semiconductor structure depicted in FIG. 2 is the base structure for forming the nanosheet devices, the finFET devices, and the hybrid MIM capacitors depicted later in FIG. 20.

As known to one skilled in the art, the nanosheet stack is formed using known semiconductor processes such as epitaxy to grow a number of very thin layers (e.g., 2 nm to 20 nm thick) of semiconductor materials that typically are alternated in the nanosheet stack. For example, layers of silicon and silicon germanium may form the nanosheet stack.

Substrate 2 can be a semiconductor substrate. In various embodiments, substrate 2 is composed of silicon. In other embodiments, substrate 2 is composed of a group IV semiconductor material, a group II-VI semiconductor material, or a group IV semiconductor material. For example, substrate 2 may be composed of but not limited to SiC, SiGe, GaAs, or InAs, ZnTe, CdTe, ZnCdTe, GaAlAs, InGaAs, InAlAs, InAlAsSb, InAlAsP, and InGaAsP. In various embodiments, substrate 2 is a wafer or a portion of a wafer. In some embodiments, substrate 2 is one of doped, undoped, or contains doped regions, undoped regions, or defect rich regions. In an embodiment, substrate 2 is one of a layered semiconductor substrate, such as a semiconductor-on-insulator substrate (SOI), Ge on insulator (GeOI) or silicon-on-replacement insulator (SRI).

Etch stop 3 resides on substrate 2 using an epitaxially growth process. In various embodiments, etch stop 3 is composed of a semiconductor material. For example, etch stop 3 can be comprised of SixGey where x and y represent the relative atomic concentration of silicon (Si) and germanium (Ge), respectively. X and y are less than 1 and their sum is equal to 1. In some embodiments, x is equal to 0.70 and y is equal to 0.30 but the concentrations of Si and Ge are not limited to these concentrations or these specific semiconductor materials.

Semiconductor 4 on etch stop 3 may be formed using epitaxially grown. In various embodiments, semiconductor 4 is silicon. In other embodiments, semiconductor 4 is composed of any of the semiconductor materials used for substrate 2 (e.g., SiC, SiGe, etc.).

Bottom sacrificial layer 5 resides on semiconductor 4. Bottom sacrificial layer 5 can be composed of any semiconductor material formed by epitaxy on semiconductor 4. In various embodiment, bottom sacrificial layer 5 is SiGe. For example, bottom sacrificial layer 5 can be comprised of Si₀₄₅Ge_{0.55} but the concentrations of Si and Ge are not limited these concentrations or these materials. In the nanosheet stack, sacrificial material 6 on bottom sacrificial layer 5 can be composed of any semiconductor material typically used in a nanosheet stack. In various embodiments, sacrificial material 6 is composed of SiGe. For example, sacrificial material 6 may have a composition of Si_{0.70} Ge_{0.30} but is not limited to this composition or materials. As known to one skilled in the art, using semiconductor materials with a different composition for sacrificial material 6, bottom sacrificial layer 5, and etch stop 3 can provide an ability to selectively etch remove on or more of these semiconductor materials.

As depicted in FIG. 2, a first or bottom layer of channel material 7 is epitaxially grown on a bottom layer of sacrificial material 6. Channel material 7 can be composed of any semiconductor material. In various embodiments, channel material 7 is silicon.

FIG. 3 depicts cross-sectional views X-X, Y1-Y1, and Y2-Y2 of the semiconductor structure after hard mask 30 patterning, removing the nanosheet stack composed of channel material 7 and sacrificial material 6 and bottom sacrificial layer 5 from the finFET device region depicted in cross-section Y1-Y1 and the MIM capacitor region depicted in cross-section Y2-Y2, in accordance with an embodiment of the present invention. As depicted in FIG. 3, a portion of hard mask 30 remains on the top surface of channel material 7 in the nanosheet stack depicted of the nanosheet device region depicted in cross-section X-X. Semiconductor 4 on etch stop remains in each cross-sections X-X, Y1-Y1, and Y2-Y2, as depicted in FIG. 3. Bottom sacrificial layer 5 remains in cross-section X-X of the nanosheet region.

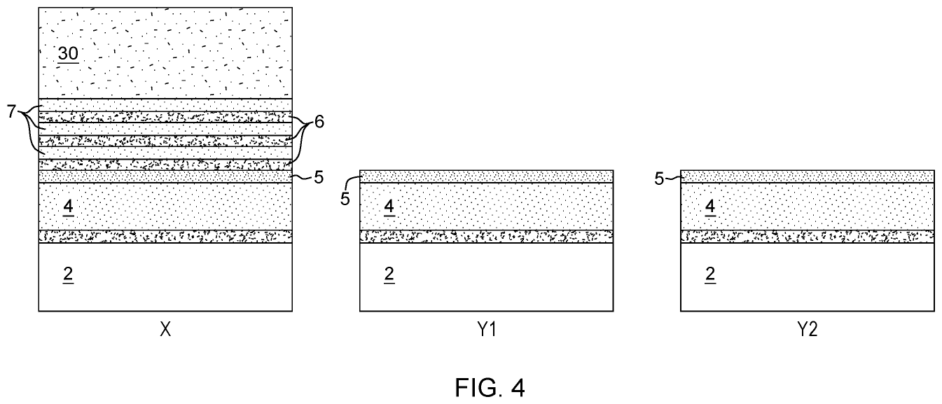

FIG. 4 depicts cross-sectional views X-X, Y1-Y1, and Y2-Y2 of the semiconductor structure after growing another layer of bottom sacrificial layer 5 on semiconductor 4 in cross-section Y1-Y1 of the finFET device region and cross-section Y2-Y2 of the MIM capacitor region, in accordance with an embodiment of the present invention. As depicted, FIG. 4 includes the elements of FIG. 3 with another or replacement layer of bottom sacrificial layer 5 epitaxially grown on semiconductor 4 in the finFET device region of cross-section Y1-Y1 and the MIM capacitor region of cross-section Y2-Y2.

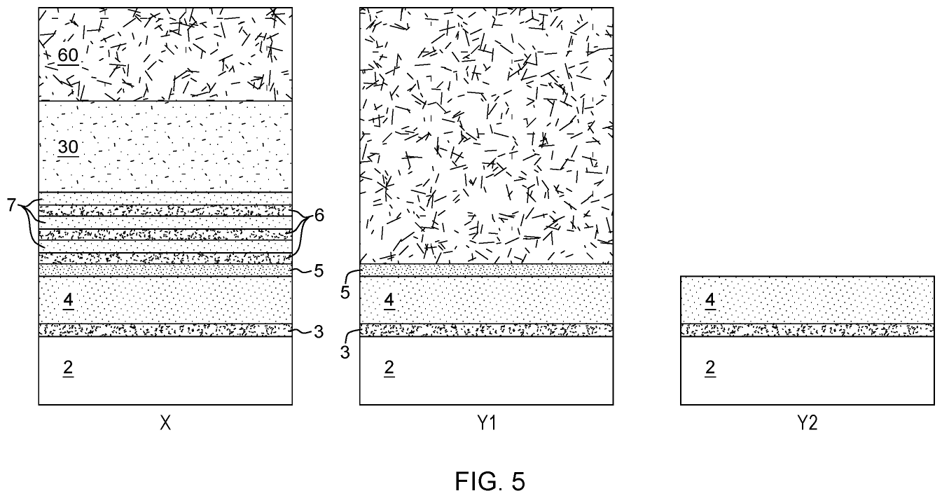

FIG. 5 depicts cross-sectional views X-X, Y1-Y1, and Y2-Y2 of the semiconductor structure after depositing and patterning OPL 60 and removing bottom sacrificial layer 5 from the MIM capacitor region, in accordance with an embodiment of the present invention. As depicted, FIG. 5 includes the elements of FIG. 4 with patterned OPL 60 on HM30 in the nanosheet device region depicted in cross-section X-X and on bottom sacrificial layer 5 in cross-section Y1-Y1 of the finFET device region but without bottom sacrificial layer 5 in the MIM capacitor region. The layer of bottom sacrificial layer 5 on semiconductor substrate 2 is removed using known semiconductor wet or dry etching processes (e.g., reactive ion etch also known as RIE) from the top surface of semiconductor 4 in cross-section Y2-Y2 of the MIM capacitor region.

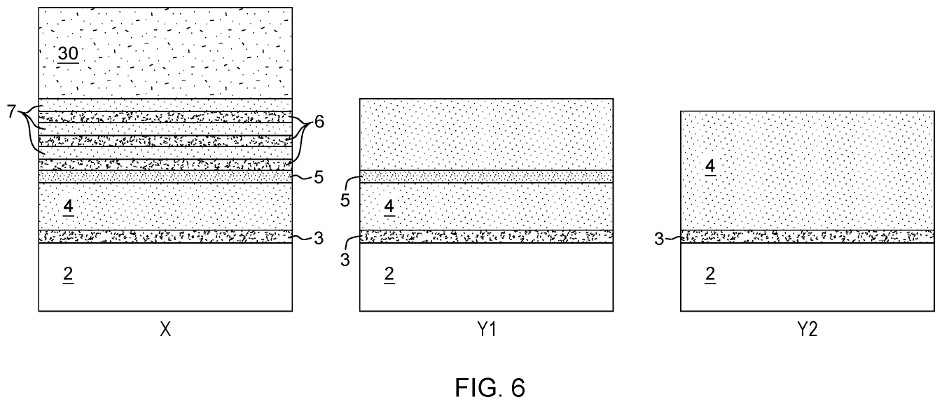

FIG. 6 depicts cross-sectional views X-X, Y1-Y1, and Y2-Y2 of the semiconductor structure after epitaxially growing semiconductor 4 on a top surface of the finFET device region and the MIM capacitor region, in accordance with an embodiment of the present invention. As depicted, FIG. 6 includes the elements of FIG. 5 with another layer of semiconductor 4 on bottom sacrificial layer 5 in cross-section Y1-Y1 and on semiconductor 4 in cross-section Y2-Y2. Semiconductor 4 is epitaxially grown on the top surfaces of bottom sacrificial layer 5 in the finFET device region depicted in cross-section Y1-Y1 and on semiconductor 4 in the MIM capacitor region depicted in cross-section Y2-Y2.

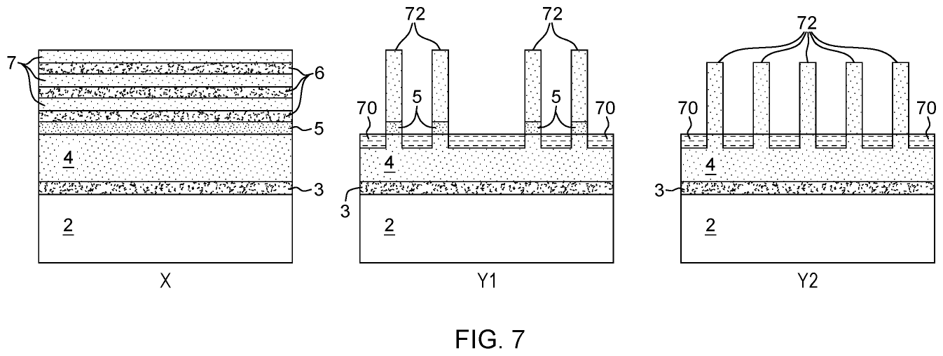

FIG. 7 depicts cross-sectional views X-X, Y1-Y1, and Y2-Y2 of the semiconductor structure after nanosheet stack patterning, fins 72 formation and STI 70 formation, in accordance with an embodiment of the present invention.

In the finFET device region depicted in cross-section Y1-Y1 and the MIM capacitor region depicted in cross-section Y2-Y2. after patterning the top surface of semiconductor 4, the exposed portions of semiconductor 4 are removed to form multiple fins 72.

As depicted in cross-section Y1-Y1, the exposed top portion of semiconductor 4, bottom sacrificial layer 5, and a top portion of semiconductor 4 under bottom sacrificial layer 5 are removed in the finFET device region to form each of fins 72 above and partially below bottom sacrificial layer 5. In the finFET device region, fins 72 can include a portion of bottom sacrificial layer 5 remains in each of fins 72 formed from semiconductor 4. A small portion of semiconductor 4 under the remaining portions of bottom sacrificial layer 5 in fins 72 also remains after etching, for example using RIE. In various embodiments, fins 72 are composed of the remaining top portions of semiconductor 4. Fins 72 in cross-section Y1-Y1 rise above the remaining portions of bottom sacrificial layer 5. In various embodiments, fins 72 is composed of silicon. A bottom portion of semiconductor 4 forms a layer of semiconductor 4 above etch stop 3.

As depicted in cross-section Y2-Y2, the exposed top portions of semiconductor 4 can be removed in the MIM capacitor region to form fins 72 and leaves a top portion of the layer of semiconductor 4 over etch stop 3. The group of fins 72 in cross-section Y2-Y2, like the group of fins 72 in cross-section Y1-Y1 is composed the remaining portions of semiconductor 4. Fins 72 rise above the remaining layer of semiconductor 4 above etch stop 3.

A dielectric material for STI 70 is deposited using a known semiconductor deposition processes (e.g., CVD, PVD, etc.) on the remaining layer of semiconductor 4 on etch stop 3 and around the bottom portions of fins 72 in the nanosheet device region (not shown, in FIG. 7), in the finFET device region depicted in cross-section Y1-Y1 and the MIM capacitor region depicted in cross-section Y2-Y2.

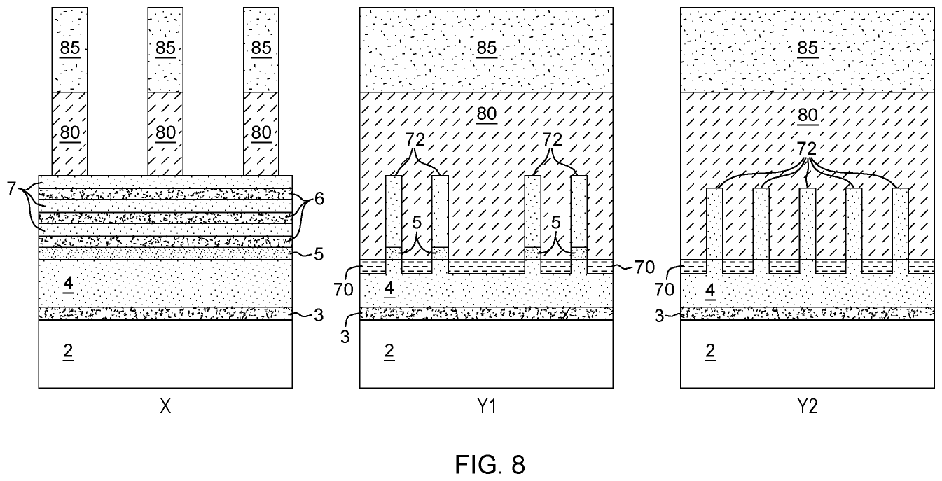

FIG. 8 depicts cross-sectional views X-X, Y1-Y1, and Y2-Y2 of the semiconductor structure after depositing dummy gate 80 and hard mask 85 and patterning dummy gate 80, in accordance with an embodiment of the present invention. As depicted, FIG. 8 includes the elements of FIG. 7 and dummy gate 80 under hard mask 85.

In the nanosheet device region depicted in cross-section X-X, three portions of dummy gate 80 remain under three portions of hard mask 85 on the nanosheet stack after etching hard mask 85 and dummy gate 80.

In the finFET device region depicted in cross-section Y1-Y1, dummy gate 80 and hard mask 85 remain over the exposed surfaces of fins 72, bottom sacrificial layer 5, and STI 70. Similarly, in the MIM capacitor region depicted in cross-section Y2-Y2, dummy gate 80 and hard mask 85 remain over the exposed surfaces of fins 72 and the top surface of STI 70. No portion of bottom sacrificial layer 5 remains in the MIM capacitor region.

FIG. 9 depicts cross-sectional views X-X, Y1-Y1, and Y2-Y2 of the semiconductor structure after removing bottom sacrificial layer 5 in the nanosheet region and the finFET device region, in accordance with an embodiment of the present invention. As depicted, FIG. 9 includes the elements of FIG. 8 without bottom sacrificial layer 5.

In the nanosheet device region depicted in cross-section X-X, bottom sacrificial layer 5 under the nanosheet stack can be removed using a wet or dry etch process such as a gas phase hydrogen chloride (HCl) etch, a wet etch process containing a mix of ammonia and hydrogen peroxide, or a dry etch such as plasma etch. Bottom sacrificial layer 5 over semiconductor 4 and under sacrificial material 6 in the nanosheet stack is removed.

In the finFET device region depicted in cross-section Y1-Y1, the remaining portions of bottom sacrificial layer 5 under each of fins 72 and above the remaining portions of semiconductor 4. Bottom sacrificial layer 5 can be selectively removed using the wet or dry etching process. Cross-section Y2-Y2 in the MIM capacitor region of FIG. 9 is the same as the Y2-Y2 cross-section in FIG. 8.

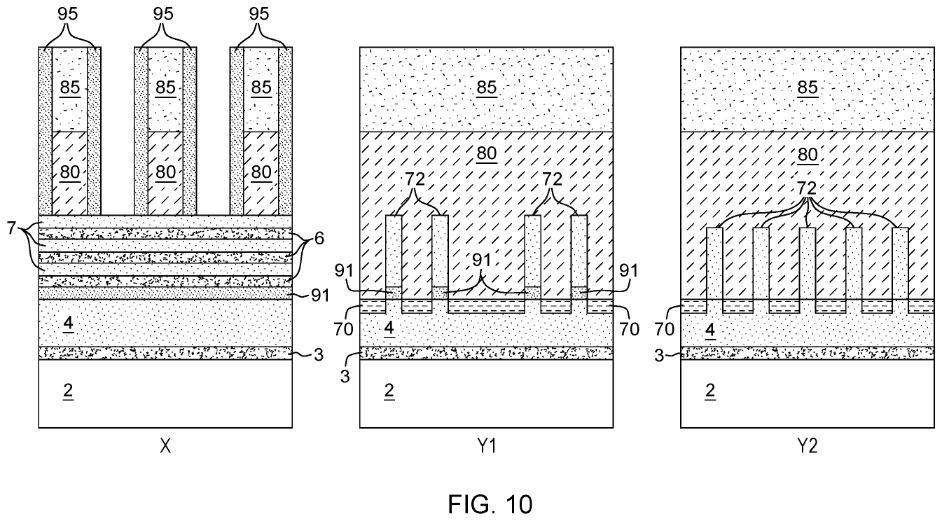

FIG. 10 depicts cross-sectional views X-X, Y1-Y1, and Y2-Y2 of the semiconductor structure after depositing BDI 91 in the nanosheet device region and the finFET device region and forming gate spacers 95 in the nanosheet device region, in accordance with an embodiment of the present invention. As depicted, FIG. 10 includes the elements of FIG. 9 with BDI 91 and gate spacers 95.

In the nanosheet device region depicted in cross-section X-X, a dielectric material for BDI 91 can be deposited under the bottom layer of sacrificial material 6 in the nanosheet stack and above semiconductor 4. BDI 91 can replace the removed bottom sacrificial layer 5. In various embodiments, BDI 91 is composed of a high-k dielectric material.

Forming gate spacers 95 can involve a conformal dielectric deposition, such as ALD, and an anisotropic RIE to remove the dielectric spacer material from horizontal surfaces of the top layer of channel material 7. In various embodiments, gate spacers 95 are a low-k nitride material. In some embodiments, gate spacers 95 and BDI 91 are the same dielectric material. Gate spacers 95 may be a dielectric material (e.g., SiN, SiBCN, SiOCN, SiOC, and the like). Gate spacers 95 can be formed around the sidewalls of dummy gate 80 and hard mask 85 on portions of the top channel layer 6 in the nanosheet stack. A directional etch process, such as an RIE, removes horizontal portions of gate spacers 95.

In the finFET device region depicted in cross-section Y1-Y1, the deposition of BDI 91 replaces the removed portions of bottom sacrificial layer 5 under each of fins 72. BDI 91 separates fin 71 from semiconductor 4 below BDI 91. Cross-section Y2-Y2 in the MIM capacitor region of FIG. 10 is the same as the Y2-Y2 cross-section in FIG. 9.

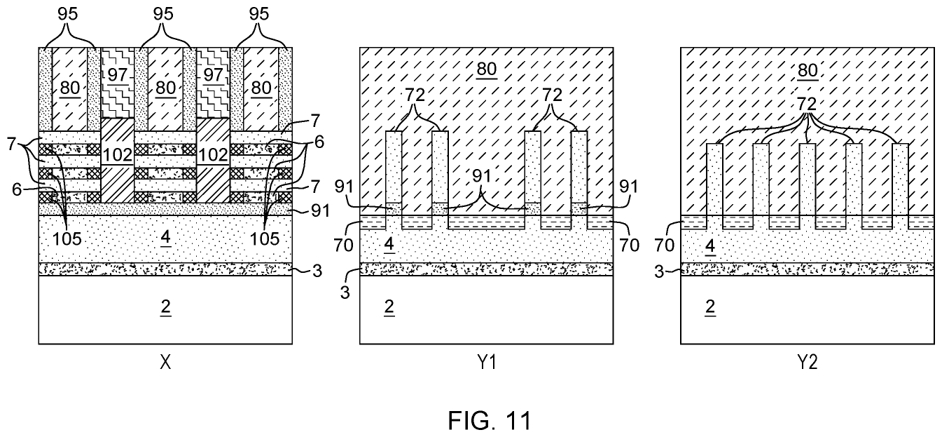

FIG. 11 depicts cross-sectional views X-X, Y1-Y1, and Y2-Y2 of the semiconductor structure after removing portions of the nanosheet stack, recessing the edges of sacrificial material 6, forming inner spacers 105, source/drains 102, ILD 97 deposition in the nanosheet device region, and performing a CMP, in accordance with an embodiment of the present invention.

In the nanosheet device region depicted in cross-section X-X, using known nanosheet device formation processes, the exposed portions of the nanosheet stack not under gate spacers 95 or hard mask 85 can be removed, for example using RIE. Portions of BDI 91 are exposed between the remaining portions of the nanosheet stack.

A lateral etching process, for example, an isotropic etch such as gas phase etch, plasma etch, or wet etch such as a hot phosphoric acid, recesses the exposed outside edges or sidewalls of each layer of sacrificial material 6 in the remaining portions of the nanosheet stack. Inner spacers 105 can be a dielectric material, such as SiN, deposited directly abutting the recessed sacrificial material 6.

Source/drains 102 can be epitaxially grown upon the exposed edges of channel material 7 (e.g., the Si nanosheets) and can be in contact with inner spacers 105 and a bottom portion of gate spacers 95. In an embodiment, the source/drain regions extend to contact all of the nanosheets of the stack. Source/drains 102 can be doped with either a p-type dopant (e.g., boron, aluminum, etc.) or an n-type dopant (e.g., antimony, phosphorous, etc.).

ILD 97 is deposited over the semiconductor structure. A CMP removes excess ILD 97 from the top surface of gate spacers 95 and hard mask 85. The CMP exposes the top surface of dummy gate 80 in the nanosheet device region depicted in cross-section X-X, cross-sections Y1-Y1 and cross-section Y2-Y2.

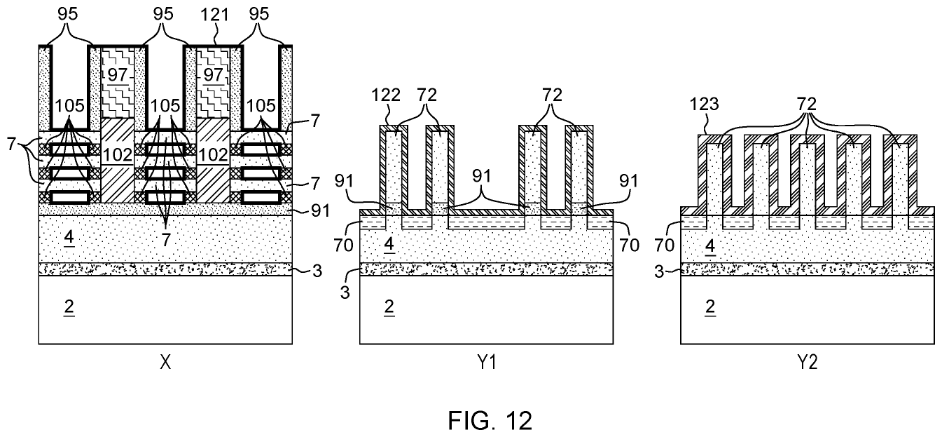

FIG. 12 depicts cross-sectional views X-X, Y1-Y1, and Y2-Y2 of the semiconductor structure after dummy gate 80 removal from all three cross-sections and sacrificial material 6 removal in the nanosheet device region followed by a dielectric material deposition in each of the three cross-sections in accordance with an embodiment of the present invention. As depicted, FIG. 12 includes the elements of FIG. 11 without dummy gate 80, without sacrificial material 6 in the nanosheet device region, and with high-k gate dielectric 121 in the nanosheet device region, thick gate dielectric 122 in the finFET device region, and insulator 123 in the MIM capacitor region.

In the nanosheet device region depicted in cross-section X-X, a thin layer of high-k gate dielectric can be deposited around the exposed surfaces of channel material 7, inner spacers 105, BDI 91, gate spacers 95, and the top surface of ILD 97. In various embodiments, high-k gate dielectric 121 is composed of hafnium dioxide (HfO₂). High-k gate dielectric 121 can be composed of other high-k dielectric materials such as but not limited to hafnium silicon oxide, hafnium silicon oxynitride, lanthanum oxide, lanthanum aluminum oxide, and the like. High-k gate dielectric 121 can be deposited in a thin layer (e.g., approximately, 1 nm to 5 nm) using ALD, CVD, or another semiconductor deposition process suitable thin film deposition. High-k gate dielectric 121 is not limited to HfO₂ and may be another dielectric material or another high-k dielectric material (e.g., with a dielectric constant greater than 9). The thickness of high-k gate 121 in the nanosheet device region is the range of 2 to 5 nm but is not limited to these thicknesses.

In the finFET device region depicted in cross-section Y1-Y1, thick gate dielectric 122 can be deposited on fins 72, the remaining portions of BDI 91 under fins 72, and on exposed surfaces of STI 70. In various embodiments, thick gate dielectric 122 is a thick gate oxide which may be formed by depositing two oxide materials using ALD, CVD, PVD, etc. In some embodiments, thick dielectric 122 is composed of a layer of HfO₂ with a layer of SiO₂. For example, a 5 nm layer of SiO₂ is deposited over fins 72, exposed surfaces of STI 70 and BDI 91 sidewalls followed by a second dielectric material such as HfO₂ (i.e., high-k gate dielectric 121). The thickness of thick gate dielectric 122 may be 7 nm to 10 nm but, is not limited these thicknesses or these dielectric materials.

In the MIM capacitor region depicted in cross-section Y2-Y2, insulator 123 is a dielectric material deposited on exposed surfaces of fins 72 and STI 70. Insulator 123 will be the insulator between the two metal plates of the MIM capacitor formed later. In various embodiments, insulator 123 is composed of a high-k gate dielectric, such as HfO₂, ZrO₂, HfZrO₂, HfTaOx, HfTiOx, etc., or super high-k dielectric material. X may be any integer greater than one. A high-k dielectric material for the purposes of the present invention can have a dielectric constant greater 10. Super high-k dielectric materials have a dielectric constant greater than 20000. For example, insulator 123 may be composed of CaCu₂Ti₃O₄ (also known as CCTO) or LaSrNi₄O₁₂ (also known as LRNO with dielectric constant >100000) but is not limited to these materials. Insulator 123 deposited by ALD. CVD, or PVD, for example, may have a thickness ranging from 2 nm to 100 nm but is not limited these thicknesses.

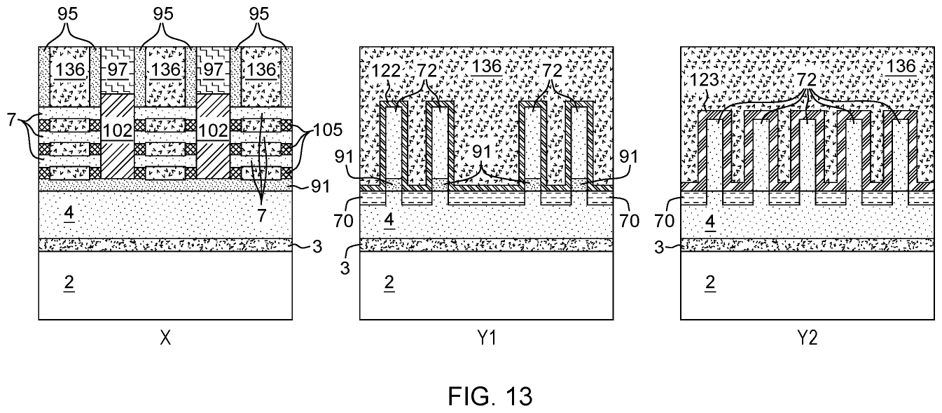

FIG. 13 depicts cross-sectional views X-X, Y1-Y1, and Y2-Y2 of the semiconductor structure after depositing gate metal 136 and performing a CMP, in accordance with an embodiment of the present invention. Deposited using known metal gate deposition processes, gate metal 136 can be any metal material suitable for a metal gate such as tantalum (Ta), tungsten (W), ruthenium (Ru), titanium nitride (TiN), tantalum nitride (TaN), Cu, or other metal material or metal alloy. In some cases, other materials such as a work function metal may be deposited with gate metal 136. In various embodiments, gate metal 136 is different metal in the nanosheet device region, in the finFET device region, and the MIM capacitor region. In some embodiments, gate metal 136 is the same material in the nanosheet device region and the finFET device region and different metal material in the MIM capacitor region.

In the nanosheet device region depicted in cross-section X-X, gate metal 136 fills the recesses between gate spacers 95 and inner spacers 105 above BDI 91. Gate metal 136 separates the center portion of each layer of channel material 7.

In the finFET device region depicted in cross-section Y1-Y1, gate metal 136 resides directly on thick gate dielectric 122. In the MIM capacitor region depicted in cross-section Y1-Y1, gate metal 136 resides on insulator 123.

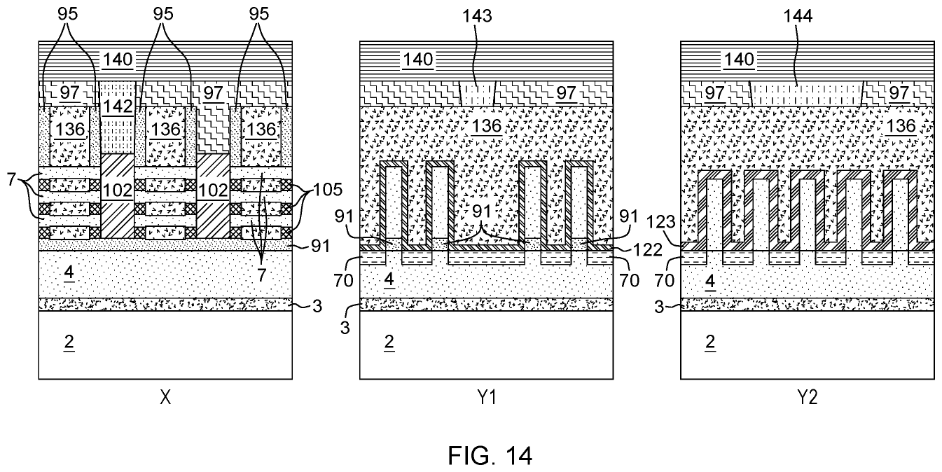

FIG. 14 depicts cross-sectional views X-X, Y1-Y1, and Y2-Y2 of the semiconductor structure after depositing another layer of ILD 97 over the semiconductor structure, forming contact 142, 143, and 144, and BEOL interconnect wiring 140, in accordance with an embodiment of the present invention. BEOL interconnect wiring 140 is a number of frontside BEOL interconnect layers formed above the MOL and the FEOL devices and wiring.

In the nanosheet device region depicted in cross-section X-X, ILD 97 is deposited over gate spacers 95, gate metal 136, source/drain 120, and ILD 97. A CMP may be performed before forming contact 142 connecting to the leftmost source/drain 120 depicted in FIG. 12. Contact 142 can be composed of any known contact metal. Using known BEOL interconnect formation processes, BEOL interconnect wiring 140 can be formed over the exposed surfaces of ILD 97 and contact 142. As known to one skilled in the BEOL interconnect wiring 140 may be composed of one or more layers of wiring, interlayer dielectric materials, and vias and may have additional semiconductor features.

In the finFET device region depicted in cross-section Y1-Y1, using similar or the same processes discussed above with reference to cross-section X-X, ILD 97 can be deposited over gate metal 136. Contact 143 connecting gate metal 136 with BEOL interconnect wiring 140 may be formed.

In the MIM capacitor region depicted in cross-section Y2-Y2, using similar or the same processes discussed above, ILD 97 is deposited over gate metal 136. In the completed MIM capacitor depicted in FIG. 20, gate metal 136 acts as a top metal plate of the MIM capacitor. Contact 144 can be formed using known contact formation process and connects gate metal 136 to BEOL interconnect wiring 140. BEOL interconnect wiring 140 can be formed over ILD 97 and contact 144.

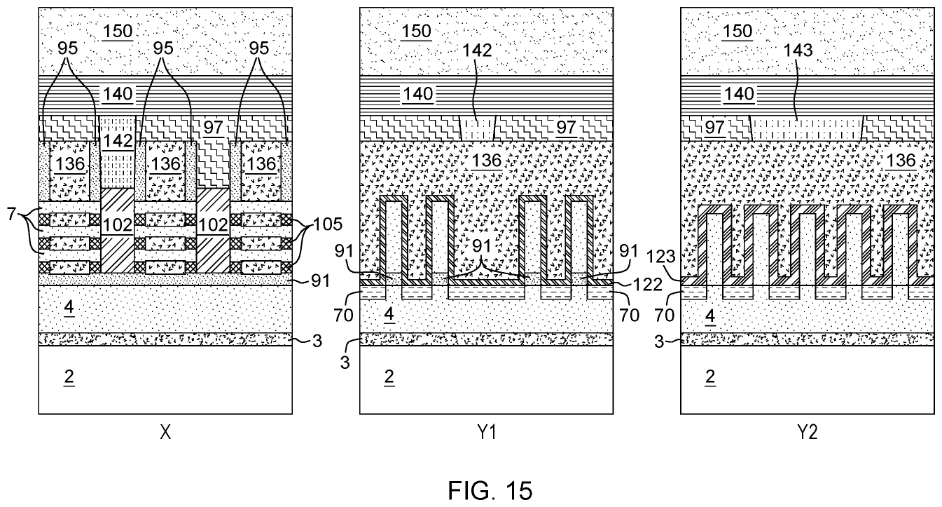

FIG. 15 depicts cross-sectional views X-X, Y1-Y1, and Y2-Y2 of the semiconductor structure after bonding carrier wafer 150 to the top surface of BEOL interconnect wiring 140, in accordance with an embodiment of the present invention. As depicted, carrier wafer 150 is bonded to the exposed surface of BEOL interconnect wiring 140. Carrier wafer 150 can be directly over BEOL interconnect wiring 140 in each of cross-section X-X, Y1-Y1, and Y2-Y2 as depicted in FIG. 15.

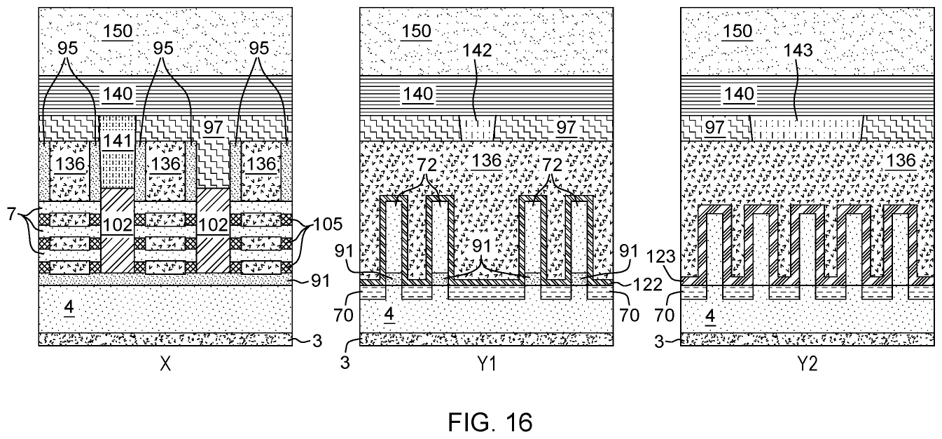

FIG. 16 depicts cross-sectional views X-X, Y1-Y1, and Y2-Y2 of the semiconductor structure after wafer flip and substrate 2 removal, in accordance with an embodiment of the present invention. While not depicted as a flipped wafer or a flipped semiconductor structure in FIG. 16, the semiconductor structure of FIG. 16 is flipped exposing substrate 2 as the top surface of the semiconductor structure. Using known wafer removal processes such as a wet etch and/or wafer grind, substrate 2 is removed using etch stop 3 to substrate 2 removal process. After removing substrate 2, etch stop 3 is exposed in each of cross-section X-X, Y1-Y1, and Y2-Y2.

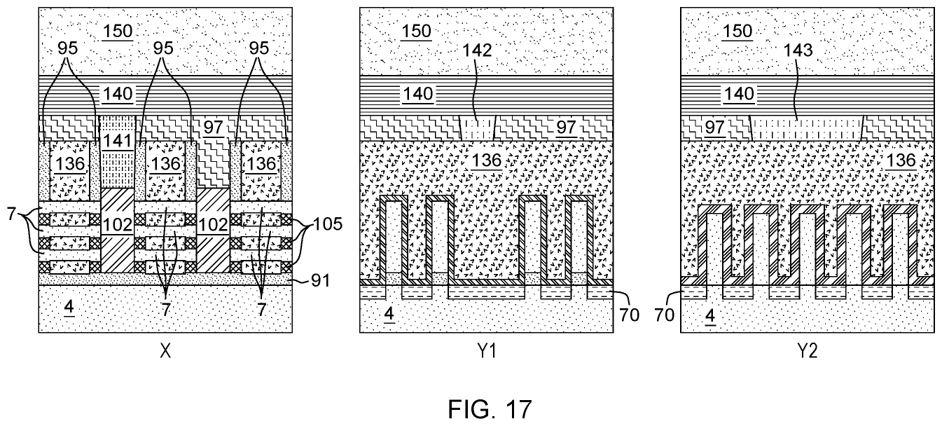

FIG. 17 depicts cross-sectional views X-X, Y1-Y1, and Y2-Y2 of the semiconductor structure after etch stop 3 removal, in accordance with an embodiment of the present invention. Using a wet or dry etch process, etch stop 3 is removed in cross-section X-X, Y1-Y1, and Y2-Y2 exposing the surface of semiconductor 4.

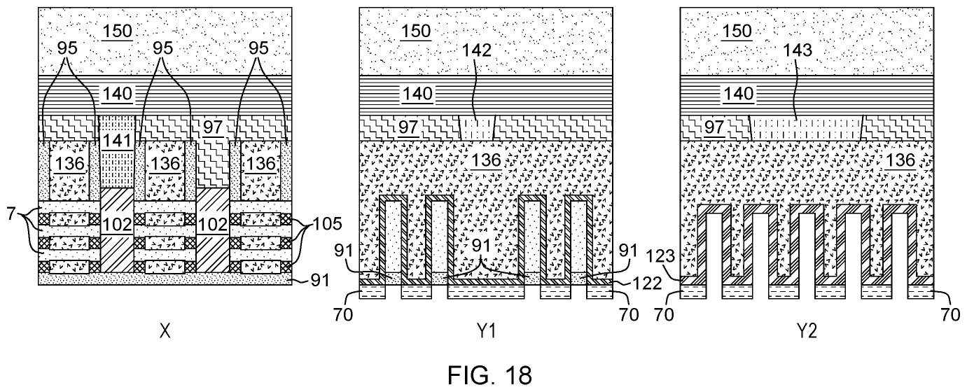

FIG. 18 depicts cross-sectional views X-X, Y1-Y1, and Y2-Y2 of the semiconductor structure after selectively removing semiconductor 4, in accordance with an embodiment of the present invention. Semiconductor 4 can be removed using one or more wet or dry etching processes. The etching processes stopping at a dielectric material above semiconductor 4. Carrier wafer 150 remains over the top surface of BEOL interconnect wiring 140 in all three cross-sections (i.e., cross-section X-X, Y1-Y1, and Y2-Y2).

In the nanosheet device region depicted in cross-section X-X, semiconductor 4 can be removed exposing the surfaces of BDI 91 under the nanosheet devices.

In the finFET device region depicted in cross-section Y1-Y1, the removal of semiconductor 4 stops at STI 70 and the remaining portions of BDI 91. The remaining portions of BDI 91, as depicted in cross-section Y1-Y1, are under fins 72.

In the MIM capacitor region depicted in cross-section Y2-Y2, semiconductor 4 is removed directly under STI 70 and insulator 123. Fins 72 are composed of the same material as semiconductor 4 and as depicted in cross-section Y2-Y2, fins 72 are also removed. After removing semiconductor 4 and fins 72, the surfaces of insulator 123 are exposed. STI 70 sidewalls and bottom surface in cross-section Y2-Y2 are also exposed.

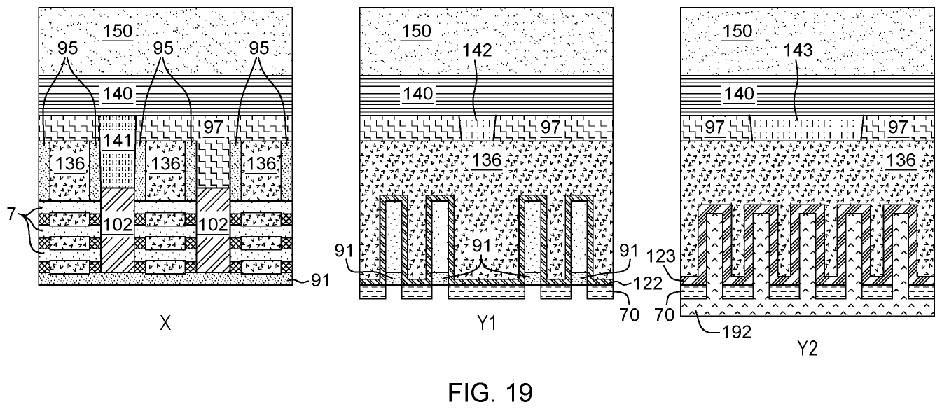

FIG. 19 depicts cross-sectional views X-X, Y1-Y1, and Y2-Y2 of the semiconductor structure after depositing backside metal plate 192 in the MIM capacitor region, in accordance with an embodiment of the present invention. As depicted, cross-sections X-X and Y1-Y1 of FIG. 19 are essentially the same as cross-sections X-X and Y1-Y1 in FIG. 18.

In the MIM capacitor region depicted in cross-section Y2-Y2, cross-section Y2-Y2 of FIG. 19 includes the elements of cross-section Y2-Y2 of FIG. 18 and backside metal plate 192. In various embodiments, backside metal plate 192 is directly contacting STI 70 and insulator 123 in the recesses formed after removing fins 72 composed of semiconductor 4. Backside metal plate 192 may be deposited by ALD, CVD, PVD, or electroless plating. Backside metal plate 192 can be composed of any metal material suitable for forming a MIM capacitor. For example, backside metal plate 192 may be composed of but not limited to Ti, Cu, Co. W. Ru, Ta, TaN, TiN, RuN, RuTa, WN, or any combination thereof.

Increasing the contact area of insulator 123 with gate metal 136 which can also be called a frontside metal plate and backside metal plate 192 by filling the recesses created with the removal of fins 72 increases the capacitance of each of the resulting MIM capacitors. The vertical sidewalls of backside metal plate 192 above STI 70 and the top surface backside metal plate 192 that directly contact insulator 123 and insulator 123 directly contacting the sidewalls of gate metal 136 and top surface of gate metal 136 each form a MIM capacitor. Unlike a conventional two-dimensional MIM capacitor, the three-dimensional structures created when backside metal plate 192 above STI 70 sandwiches insulator 123 below gate metal 136 creates a large surface area of contact between the two metal plates (i.e., backside metal plate 192 and gate metal 136) and insulator 123. Insulator 123 has contact areas between the frontside metal plate formed by gate metal 136 and backside metal plate 192 in the vertical metal fins and on a top surface of each of vertical metal fins replacing fins 72. Using both the top surface and vertical sidewalls formed by the removal of fins 72 enlarges the contact surface area of insulator 193 with the two metal plates compared to conventional two-dimensional MIM capacitors with the same horizontal footprint. The semiconductor structure of cross-section Y2-Y2 in FIG. 19 depicts a novel, three-dimensional MIM capacitors. For example, the width of backside metal plate 192 extending into the space of the removed fins 72 can be in the range of 5 to 15 nm and with a height in the range of 20 to 80 nm but is not limited to these dimensions.

Essentially, as depicted in FIG. 19 cross-section Y2-Y2, five hybrid or fin-like three-dimensional MIM capacitors are formed. The hybrid or fin-like MIM capacitors using both horizontal and vertical sides of portions of backside metal plate 192 filling the recesses formed when fins 72 were removed greatly increase the contact area of insulator 123 with the two metal plates as insulator 123 is surrounded above and below by gate metal 136 and backside metal plate 192. In this way, the three-dimensional MIM capacitors are high density MIM capacitors that provide more capacitance to other connected devices than conventional MIM capacitors with the same footprint. The high-density MIM capacitors of FIG. 19 provide both increased capacitance and a potential for increased MIM capacitor density (e.g., reduced wafer area) for the same generated capacitance as conventional MIM capacitors.

FIG. 20 depicts cross-sectional views X-X, Y1-Y1, and Y2-Y2 of the semiconductor structure after depositing backside ILD 127, forming backside contact 194 in the nanosheet device region and backside contact 196 in the MIM capacitor region, and backside BEOL interconnect wiring 190, in accordance with an embodiment of the present invention. In various embodiments, backside BEOL interconnect wiring 190 are a backside power delivery network.

In the nanosheet device region depicted in cross-section X-X, backside ILD 127 is deposited under BDI 91. BDI 91 is under three nanosheet devices composed of channel material 7, source/drain 120, gate structures composed of at least gate metal 136, high-k gate dielectric 121, inner spacers 105, and gate spacers 95. One of source/drain 120 connect to BEOL interconnect wiring 140 by contact 141 and a second source/drain 120 connects to backside BEOL interconnect wiring 190 by backside contact 194. Carrier wafer 150 remains directly on BEOL interconnect wiring 140. Backside contact 194 can be formed in backside ILD 127. Backside BEOL interconnect wiring 190 can be formed under backside ILD 127.

In the finFET device region depicted in cross-section Y1-Y1, backside BEOL interconnect wiring 190 is under backside ILD 127 and below four finFET devices each composed one of fins 72 surrounded on top and sidewalls with thick gate dielectric 122. Gate metal 136 is over thick gate dielectric 122. Contact 142 extends through ILD 97 to connect with BEOL interconnect wiring 140 under carrier wafer 150. In various embodiments, each of the four finFETs can receive additional capacitance from the high density MIM capacitors depicted in cross-section Y2-Y2 through contact 142 and BEOL interconnect wiring 140. Additionally, the four finFET devices in cross-section Y1-Y1 can connect to the nanosheet devices in cross-section X-X through contact 142, BEOL interconnect wiring 140, and contact 141.

The fin-like, high density MIM capacitors of cross-section Y2-Y2 and the finFET devices depicted in cross-section Y1-Y1 can be formed with very similar or almost the same semiconductor processes. Backside contact 196 can be formed connecting to the MIM capacitors in the MIM capacitor region depicted in cross-section Y2-Y2 while portions of BDI 91 under fins 72. In the MIM capacitor region, fins 72 can be removed to form the three-dimensional, high density MIM capacitors of cross-section Y2-Y2.

In the MIM capacitor region depicted in cross-section Y2-Y2, fins 72 are replaced with backside metal plate 192 which includes vertical fin-like metal elements replacing fins 72. In various embodiments, a super high-k dielectric material forms insulator 123 of the three-dimensional, high density MIM capacitor where insulator 123 lines the recesses created by the removal of fins 72. The high density MIM capacitors of cross-section Y2-Y2 can be connected to both backside BEOL interconnect wiring 190 and BEOL interconnect wiring 140 by a top contact (i.e., contact 143) and a bottom contact (i.e., backside contact 196) to provide capacitance to the nanosheet devices with thin high-k gate dielectric 121 in cross-section X-X and the finFET devices with thick gate dielectric 122 depicted in cross-section Y1-Y1.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A semiconductor structure comprising:
a plurality of vertical metal fins on a backside metal plate, wherein the backside metal plate connects to a layer of a backside back-end-of-line (BEOL) interconnect wiring;
a high-k dielectric material directly on a top portion of each of the plurality of vertical metal fins on the backside metal plate and a surface of a shallow isolation trench between the plurality of vertical metal fins;
a frontside metal plate directly on the high-k dielectric material, wherein the frontside metal plate connects to a frontside back-end-of-line (BEOL) interconnect wiring.

2. The semiconductor structure of claim 1, wherein:
the semiconductor structure is a three-dimensional metal-insulator-metal (MIM) capacitor; and
the plurality of vertical metal fins provide:
a plurality of vertical contact areas of the high-k dielectric material with portions of the backside metal plate and portions of the frontside metal plate; and
a plurality of horizontal contact areas of the high-k dielectric material with portions of the backside metal plate and portions of the frontside metal plate on a top surface of each of the vertical metal fins.

3. The semiconductor structure of claim 1, wherein the high-k dielectric material directly on a top portion of each of the plurality of vertical metal fins of the backside metal plate and the surface of the shallow trench isolation is between the frontside metal plate and the backside metal plate.

4. The semiconductor structure of claim 1, wherein the backside metal plate with the plurality of vertical metal fins resides on a backside interlayer dielectric material, and wherein a backside interlayer dielectric material is directly on the backside BEOL interconnect wiring.

5. The semiconductor structure of claim 1, wherein the frontside metal plate is directly under an interlayer dielectric material, and wherein the interlayer dielectric material is under the frontside BEOL interconnect wiring.

6. The semiconductor structure of claim 1, wherein the high-k dielectric material has a dielectric constant greater than 20000.

7. The semiconductor structure of claim 2, wherein the high-k dielectric material directly on the top portion of each of the plurality of vertical metal fins on the backside metal plate and the surface of the shallow isolation trench between the plurality of vertical metal fins is LaSrNi₄O₁₂.

8. A semiconductor structure comprising:
a nanosheet device region, a finFET device region, and a fin-like three-dimensional MIM capacitor region in a semiconductor chip, wherein the semiconductor chip bonded to a carrier wafer has a backside back-end-of-line (BEOL) interconnect wiring.

9. The semiconductor structure of claim 8, wherein the nanosheet device region with one or more gate-all-around (GAA) nanosheet field-effect transistors (FETs) is on a bottom dielectric isolation layer, wherein the one or more GAA nanosheet FETs connect by a first frontside contact to a frontside back-end-of-line (BEOL) interconnect wiring and by a first backside contact to a backside BEOL interconnect wiring.

10. The semiconductor structure of claim 8, wherein the finFET device region with one or more finFET devices is on a bottom interlayer dielectric material, wherein the one or more finFET devices connect by a second frontside contact to a frontside BEOL interconnect wiring.

11. The semiconductor structure of claim 8, wherein the fin-like three-dimensional MIM capacitor region with one or more fin-like three-dimensional MIM capacitors, wherein the one or more three-dimensional MIM capacitors on a backside interlayer dielectric material connect be a third frontside contact to a frontside BEOL interconnect wiring and a second backside contact connects to the backside BEOL interconnect wiring.

12. The semiconductor structure of claim 10, wherein the one or more finFET devices have a thick gate dielectric under a metal gate material, and wherein a thick gate dielectric is composed of a first oxide dielectric material and a second high-k dielectric material.

13. The semiconductor structure of claim 10, wherein the one or more finFET devices have a plurality of fins residing on the bottom dielectric isolation, and wherein the bottom dielectric isolation is on the bottom interlayer dielectric material that is directly on the backside BEOL interconnect wiring.

14. The semiconductor structure of claim 8, wherein the frontside BEOL interconnect wiring is bonded to the carrier wafer.

15. The semiconductor structure of claim 9, wherein the first backside contact to the backside BEOL interconnect wiring directly contacts a top surface of a first source/drain, and wherein the first frontside contact directly contacts a bottom surface of a second source/drain.

16. The semiconductor structure of claim 11, wherein the one or more fin-like three-dimensional MIM capacitors, further comprises:
a backside metal plate with a plurality of metal fins, wherein a top portion of the plurality of metal fins is directly under a layer of a high-k dielectric material, and wherein the second backside contact connects the backside metal plate with the backside BEOL interconnect wiring; and
a frontside metal plate directly on the high-k dielectric material, wherein the frontside metal plate with the third frontside contact connects to the frontside BEOL interconnect wiring, and wherein the frontside BEOL interconnect wiring is under the carrier wafer.

17. The semiconductor structure of claim 12, wherein the high-k dielectric material has a dielectric constant greater than 20000.

18. The semiconductor structure of claim 12, wherein the one or more finFET devices with the thick gate dielectric are input/output devices in the finFET device region, and wherein the one or more GAA nanosheet FETs in the nanosheet device region are logic devices using two-nanometer technology.

19. A method of forming a semiconductor structure comprising:
forming on a semiconductor substrate one or more nanosheet devices in a nanosheet device region, one or more finFET devices in a finFET device region, and one or more three-dimensional MIM capacitors in a three-dimensional MIM capacitor region.

20. The method of claim 19, further comprises:
forming an etch stop layer on the semiconductor substrate, wherein a first silicon layer is grown by epitaxy on the etch stop layer;
forming a first bottom sacrificial layer on the first silicon layer;
forming a nanosheet stack composed of alternating layers of a sacrificial material and a channel material on the bottom sacrificial layer;
patterning a hard mask on the nanosheet device region of the semiconductor substrate;
removing the nanosheet stack and the first bottom sacrificial layer in the finFET device region and the three-dimensional MIM capacitor region of the semiconductor substrate;
epitaxially growing a second bottom sacrificial layer in the first silicon layer in the finFET device region and the three-dimensional MIM capacitor region of the semiconductor substrate;
removing the second bottom sacrificial layer in the three-dimensional MIM capacitor region;
epitaxially growing a second silicon layer in the finFET device region and the three-dimensional MIM capacitor region;
etching a plurality of fins in the second silicon layer in the finFET device region and the three-dimensional MIM capacitor region;
depositing a shallow isolation trench on exposed surfaces of the first silicon layer;
removing hard mask in the nanosheet device region;
forming a dummy gate in the nanosheet device region, the finFET device region, and the three-dimensional MIM capacitor region;
removing the first bottom sacrificial layer and the second bottom sacrificial layer;
replacing the first and the second bottom sacrificial layer with a bottom dielectric isolation layer;
forming gate spacers around the dummy gate;
using a reactive ion etching process, removing exposed portions of the nanosheet stack;
forming inner spacers below the gate spacers;
epitaxially growing one or more source/drains;
depositing and performing planarization of an interlayer dielectric;
removing the dummy gate;
removing the sacrificial material;
conformally depositing a gate dielectric material;
depositing a metal gate material and a second layer of interlayer dielectric material;
forming a source/drain contact in the nanosheet device region and a gate contact in each of the finFET device region and the three-dimensional MIM capacitor region;
forming multiple layers of BEOL interconnect wiring on the second layer of interlayer dielectric material, the source/drain contact, and the gate contact;
bonding a carrier wafer to the BEOL interconnect wiring;
removing the semiconductor substrate using wafer grinding and etch;
removing the etch stop layer;
removing the first silicon layer under the bottom dielectric isolation, the shallow isolation trench, and under the gate dielectric material in the three-dimensional MIM capacitor region;
depositing a backside metal plate in the three-dimensional MIM capacitor region;
depositing a backside interlayer dielectric material and forming backside contacts; and
forming one or more backside BEOL interconnect wiring layers.
